(19) United States
(12) Patent Application Publication
(10) Pub. No.: US 2015/0091025 A1
(43) Pub. Date: Apr. 2, 2015

(54) LIGHT-EMITTING DEVICE AND METHOD OF MANUFACTURING THE SAME

(71) Applicant: TOYODA GOSEI CO., LTD., Kiyosu-shi (JP)

(72) Inventors: Yosuke TSUCHIYA, Kiyosu-shi (JP); Hiroyuki TAJIMA, Kiyosu-shi (JP); Shota SHIMONISHI, Kiyosu-shi (JP); Shigeo TAKEDA, Kiyosu-shi (JP); Tomohiro MIWA, Kiyosu-shi (JP)

(73) Assignee: TOYODA GOSEI CO., LTD., Kiyosu-shi (JP)

(21) Appl. No.: 14/290,737

(22) Filed: May 29, 2014

(30) Foreign Application Priority Data
Sep. 30, 2013 (JP) 2013-204413

(51) Int. Cl. H01L 33/44; H01L 27/15

(52) U.S. Cl. CPC H01L 33/44; H01L 27/15
USPC 257/88; 438/28

(57) ABSTRACT

A light-emitting device includes a sheet-shaped die bonding material on a substrate including a wiring, and a plurality of light-emitting elements fixed onto the die bonding material. A method of manufacturing the light-emitting device includes applying the die bonding material in a paste form to the substrate such that the die bonding material is shared by the plurality of light-emitting elements, placing the plurality of light-emitting elements on the die bonding material in the paste form, and curing the die bonding material after placing the plurality of light-emitting elements so as to fix the plurality of light-emitting elements onto the bonding material.

The present application is based on Japanese patent application No. 2013-204413 filed on Sep. 30, 2013, the entire contents of which are incorporated herein by reference.

### BACKGROUND OF THE INVENTION

1. Field of the Invention

The invention relates to a light-emitting device and a method of manufacturing the light-emitting device.

2. Description of the Related Art

In making a light-emitting device with a light-emitting element mounted on a substrate, a die bonding which is a well-known technique is used to fix the light-emitting element onto a substrate (see e.g. JP-A-2012-004519). The die bonding is conducted such that a die bonding material is applied to each mounting position of the light-emitting elements, the light-emitting elements are mounted on the die bonding material and the die bonding material is then cured.

### SUMMARY OF THE INVENTION

In case of mounting closely plural light-emitting elements on the substrate, the mounting position of the light-emitting elements may be displaced during the die bonding. For example, the die bonding material can be spread in the horizontal direction upon mounting a light-emitting element thereon, so that the die bonding material lying under a next-mounted element may contact with the die bonding material under the previously-mounted light-emitting element. Thereby, the mounting position of the previously-mounted light-emitting element may be displaced.

It is an object of the invention to provide a light-emitting device that is configured such that the light-emitting element can be accurately mounted on the substrate by the die bonding, as well as a method of manufacturing the light-emitting device that allows the light-emitting element to be accurately mounted on the substrate by the die bonding.

(1) According to one embodiment of the invention, a light-emitting device comprises:
a sheet-shaped die bonding material on a substrate comprising a wiring; and
a plurality of light-emitting elements fixed onto the die bonding material.

In the above embodiment (1) of the invention, the following modifications and changes can be made.

(i) The die bonding material comprises a white material.

(ii) The light-emitting device further comprises a light reflective material between the substrate and the die bonding material,

wherein the die bonding material comprises a transparent material.

(2) According to another embodiment of the invention, a method of manufacturing the light-emitting device according to the above embodiment (1) comprises:

applying the die bonding material in a paste form to the substrate such that the die bonding material is shared by the plurality of light-emitting elements;

placing the plurality of light-emitting elements on the die bonding material in the paste form; and

curing the die bonding material after placing the plurality of light-emitting elements so as to fix the plurality of light-emitting elements onto the bonding material.

In the above embodiment (2) of the invention, the following modifications and changes can be made.

(iii) The die bonding material in the paste form is applied to the substrate by printing.

(iv) The die bonding material in the paste form is applied to the substrate by spin coating.

### Effects of the Invention

According to one embodiment of the invention, a light-emitting device can be provided that is configured such that the light-emitting element can be accurately mounted on the substrate by the die bonding, as well as a method of manufacturing the light-emitting device that allows the light-emitting element to be accurately mounted on the substrate by the die bonding.

### BRIEF DESCRIPTION OF THE DRAWINGS

Next, the present invention will be explained in more detail in conjunction with appended drawings, wherein:

FIG. 1 is a vertical cross-sectional view showing a light-emitting device in a first embodiment;

FIG. 2 is a top view showing the light-emitting device in which a die bonding material covers the entire upper surface of a substrate except terminal areas;

FIGS. 3A to 3D are vertical cross-sectional views showing a manufacturing process of the light-emitting device in the first embodiment; and

FIG. 4 is a vertical cross-sectional view showing a light-emitting device in a second embodiment.

### DETAILED DESCRIPTION OF THE PREFERRED EMBODIMENTS

### First Embodiment

### Structure of Light-Emitting Device

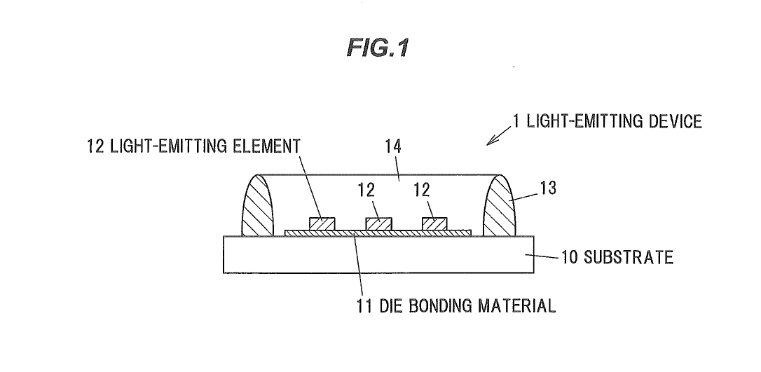

FIG. 1 is a vertical cross-sectional view showing a light-emitting device 1 in the first embodiment.

The light-emitting device 1 has a substrate 10, a sheet-shaped die bonding material 11 placed on the substrate 10, plural light-emitting elements 12 fixed on the die bonding material 11, a dam 13 surrounding the light-emitting elements 12 and a sealing resin 14 filled inside the dam 13 to seal the light-emitting elements 12.

The substrate 10 is a substrate having a wiring and is, e.g., a circuit board having a wiring pattern on a surface thereof or a lead frame inserted board.

The light-emitting element 12 is, e.g., an LED chip having a chip substrate and a crystal layer which includes cladding layers and a light-emitting layer sandwiched therebetween. Alternatively, light-emitting elements other than LED chips, such as laser diode, may be used.

The light-emitting elements 12 are connected to a conductive member included in the substrate 10, such as a wiring pattern or a lead frame, by non-illustrated bonding wires, etc., and power is externally supplied through the conductive member.

The dam 13 is formed of a resin, e.g., a silicone-based resin or an epoxy-based resin, etc., containing a white dye such as titanium oxide.

The sealing resin 14 is formed of a transparent resin, e.g., a silicone-based resin or an epoxy-based resin, etc. In addition, the sealing resin 14 may contain phosphor particles. For example, when emission color of the light-emitting element 12 is blue and fluorescence color of the phosphor particles contained in the sealing resin 14 is yellow, emission color of the light-emitting device 1 is white.

The die bonding material 11 is formed of a white thermosetting resin and has a function as a light reflecting film. A thermosetting resin used as a material of the die bonding material 11 is, e.g., an epoxy-based or silicone-based resin containing a white filler and it is especially preferable that a resin having excellent heat resistance such as dimethyl silicone be used. In addition, the white filler contained in the thermosetting resin is formed of fine particles of, e.g., titanium oxide, aluminum oxide, barium sulfate, boron nitride or aluminum nitride, etc.

In addition, since the die bonding material 11 in the first embodiment has a function as a light reflecting film, it is possible to suppress light absorption by a wiring exposed on the upper surface of the substrate 10, such as a wiring pattern when the substrate 10 is a circuit board or a lead frame when the substrate 10 is a lead frame inserted board, and it is thereby possible to improve light extraction efficiency of the light-emitting device 1. Thus, the die bonding material 11 preferably covers as large area of the wiring exposed on the upper surface of the substrate 10 as possible and preferably covers the entire area except terminal areas such as external connecting terminals or wire bonding terminals.

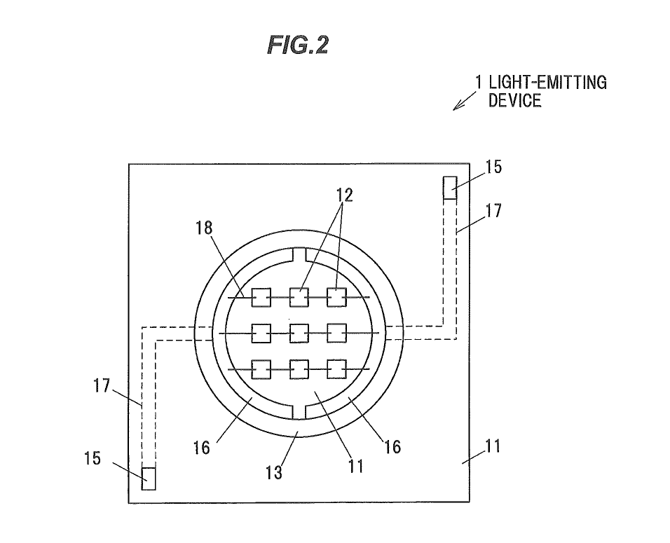

FIG. 2 is a top view showing the light-emitting device 1 in which the die bonding material 11 covers the entire upper surface of the substrate 10 except terminal areas. Note that, illustration of the sealing resin 14 is omitted in FIG. 2.

In the example shown in FIG. 2, the die bonding material 11 covers the upper surface of the substrate 10 except external connecting terminals 15 and wire bonding terminals 16, and the light-emitting elements 12 and the dam 13 are placed on the die bonding material 11.

The external connecting terminals 15 are electrically connected to the wire bonding terminals 16 by wiring electrodes 17 located under the die bonding material 11 and the light-emitting elements 12 are connected to the wire bonding terminals 16 via bonding wires 18.

### Manufacturing Process of the Light-Emitting Device

An example of a manufacturing process of the light-emitting device 1 will be described below.

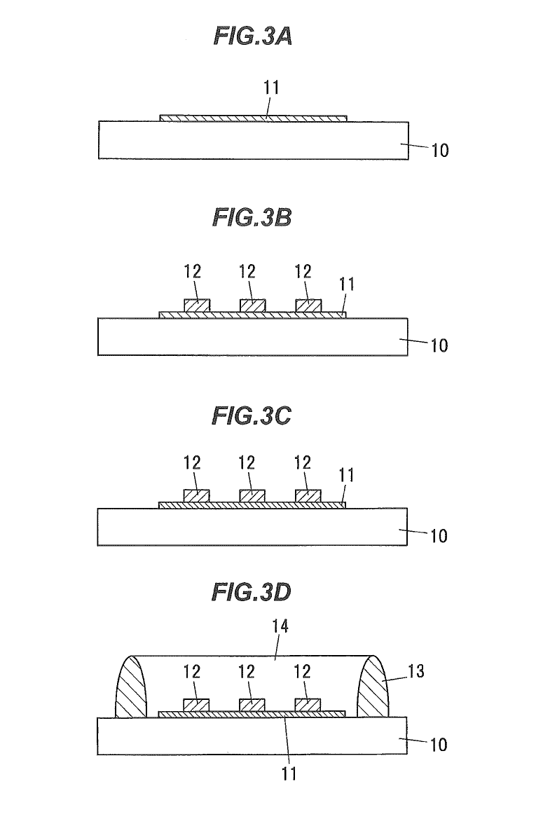

FIGS. 3A to 3D are vertical cross-sectional views showing a manufacturing process of the light-emitting device 1 in the first embodiment.

Firstly, as shown in FIG. 3A, the die bonding material 11 is applied onto the substrate 10. At this stage, the die bonding material 11 is in the paste form and has fluidity.

This die bonding material 11 in the paste form is applied onto the substrate 10 by printing such as screen printing or by spin coating. In case of using spin coating, the die bonding material 11 is applied in a state that the surfaces of terminal areas such as external connecting terminals and wire bonding terminals (e.g., the external connecting terminals 15 and the wire bonding terminals 16 shown in FIG. 2) are covered with a mask or jig so that the terminal areas are not covered with the die bonding material 11.

Next, as shown in FIG. 3B, plural light-emitting elements 12 are placed on the die bonding material 11 still in the paste form.

In the conventional die bonding method, the die bonding material is applied to each mounting position of the light-emitting element and the light-emitting element is then mounted thereon. Therefore, the die bonding material can be spread in the horizontal direction by mounting the light-emitting element, and the die bonding material lying under the next-mounted element may contact with the die bonding material under the previously-mounted light-emitting element, whereby the mounting position of the previously-mounted light-emitting element may be displaced. By contrast, in the embodiment, the problem is less likely to occur even when the plural light-emitting elements 12 are mounted close to each other since one die bonding material 11 is shared by the plural light-emitting elements 12, and the mounting positions of the light-emitting elements are less likely to be displaced.

In addition, by forming the die bonding material 11 using a material of which thixotropy or viscosity before curing is high, it is possible to effectively suppress displacement of the mounting positions of the light-emitting elements 12.

Next, as shown in FIG. 3C, the die bonding material 11 is cured by heating after the plural light-emitting elements 12 are mounted, thereby fixing the plural light-emitting elements 12.

Next, as shown in FIG. 3D, the dam 13 surrounding the light-emitting elements 12 is formed on the substrate 10 and the light-emitting elements 12 are then sealed with the sealing resin 14. In detail, a liquid resin is stacked up on the substrate 10 by potting, etc., and is cured, thereby forming the dam 13. After that, a liquid transparent resin is dropped and filled inside the dam 13 by potting, etc., and is cured, thereby forming the sealing resin 14.

### Second Embodiment

The second embodiment is different from the first embodiment in that the die bonding material is transparent. It should be noted that the explanation of the same features as the first embodiment will be omitted or simplified.

### Structure of Light-Emitting Device

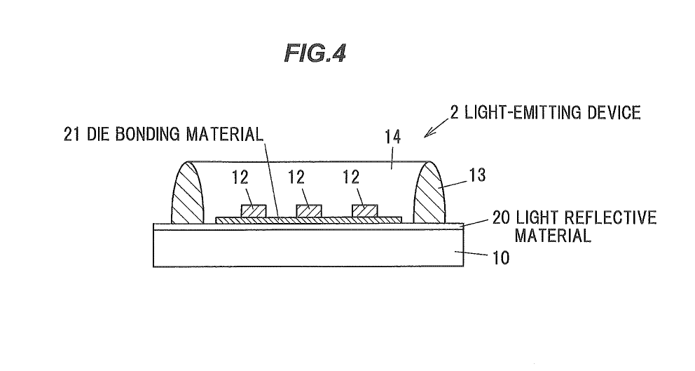

FIG. 4 is a vertical cross-sectional view showing a light-emitting device 2 in the second embodiment.

The light-emitting device 2 has a sheet-shaped die bonding material 21 placed on the substrate 10, a light reflective material 20 placed between the substrate 10 and the die bonding material 21, plural light-emitting elements 12 fixed on the die bonding material 21, the dam 13 surrounding the light-emitting elements 12 and the sealing resin 14 filled inside the dam 13 to seal the light-emitting elements 12.

The light reflective material 20 is a film formed of, e.g., a resin material containing a white filler. The white filler is formed of fine particles of, e.g., titanium oxide, aluminum oxide, barium sulfate, boron nitride or aluminum nitride, etc. Alternatively, the light reflective material 20 may be a plating film formed by plating a metal such as Ag on a surface of the substrate 10.

Alternatively, the light reflective material 20 may be formed by surface-treating the substrate 10. When the substrate 10 is, e.g., an aluminum substrate or an aluminum alloy substrate, an anodic aluminum oxide film formed by performing alumite treatment on the surface of the substrate 10 may be used as the light reflective material 20. The anodic oxide film is preferably a white anodic oxide film having excellent light reflectivity.

The die bonding material 21 is formed of a transparent thermosetting resin. A thermosetting resin used as a material of the die bonding material 21 is, e.g., an epoxy-based or silicone-based resin and it is especially preferable that a resin having excellent heat resistance such as dimethyl silicone be used.

### Effects of the Embodiments

In the first and second embodiments, since one die bonding material is shared by the plural light-emitting elements, the mounting positions of the light-emitting elements are less likely to be displaced even when plural light-emitting elements are close to each other. In addition, the die bonding material can also serve as a light reflecting film.

Although the embodiments of the invention have been described above, the invention is not intended to be limited to the embodiments and the various kinds of modifications can be implemented without departing from the gist of the invention.

In addition, the invention according to claims is not to be limited to the above-mentioned embodiments. Further, please note that all combinations of the features described in the embodiments are not necessary to solve the problem of the invention.

What is claimed is:

1. A light-emitting device, comprising:
a sheet-shaped die bonding material on a substrate comprising a wiring; and
a plurality of light-emitting elements fixed onto the die bonding material.

2. The light-emitting device according to claim 1, wherein the die bonding material comprises a white material.

3. The light-emitting device according to claim 1, further comprising a light reflective material between the substrate and the die bonding material,
wherein the die bonding material comprises a transparent material.

4. A method of manufacturing the light-emitting device according to claim 1, comprising:
applying the die bonding material in a paste form to the substrate such that the die bonding material is shared by the plurality of light-emitting elements;
placing the plurality of light-emitting elements on the die bonding material in the paste form; and
curing the die bonding material after placing the plurality of light-emitting elements so as to fix the plurality of light-emitting elements onto the bonding material.

5. The method according to claim 4, wherein the die bonding material in the paste form is applied to the substrate by printing.

6. The method according to claim 4, wherein the die bonding material in the paste form is applied to the substrate by spin coating.
